(19) United States
(12) Patent Application Publication
(10) Pub. No.: US 2016/0071780 A1
(43) Pub. Date: Mar. 10, 2016

(54) SEMICONDUCTOR PACKAGE AND METHOD OF FABRICATING THE SAME

(71) Applicant: Siliconware Precision Industries Co., Ltd., Taichung (TW)

(72) Inventors: Shih-Chao Chiu, Taichung (TW); Chun-Hsien Lin, Taichung (TW); Ming-Chen Sun, Taichung (TW); Yu-Cheng Pai, Taichung (TW); Tzu-Chieh Shen, Taichung (TW)

(73) Assignee: Siliconware Precision Industries Co., Ltd., Taichung (TW)

(21) Appl. No.: 14/603,844

(22) Filed: Jan. 23, 2015

(30) Foreign Application Priority Data
Sep. 5, 2014 (TW) 103130721

(51) Int. Cl. H01L 23/31; H01L 23/522

(52) U.S. Cl. CPC H01L 23/3157; H01L 23/5226

(57) ABSTRACT

A method of fabricating a semiconductor package is provided, including providing a carrier provided having a circuit layer and a blocking member, forming on the carrier an encapsulating layer having a first surface and a second surface opposing the first surface and encapsulating the circuit layer and the blocking member, with the first surface coupled with the carrier, and removing the carrier and the blocking member to form in the encapsulating layer via the first surface thereof an opening for an electronic component to be received therein. Before the electronic component is disposed in the opening, the circuit layer and the electronic component can be tested in advance, in order to retire the defectives. Therefore, as a defective electronic component is prevented from being disposed in the opening, no defective semiconductor package will be fabricated.

### BACKGROUND OF THE INVENTION

1. Field of the Invention

The present invention relates to packaging processes, and, more particularly, to a semiconductor package and a method of fabricating the same.

2. Description of Related Art

As the semiconductor industry advances, the demand for electronic products with light weight, low-profile, high integration and high functionality increases. Apart from a ball grid arrray (BGA) being developed to accommodate the needs for high integration and miniaturization, a flip chip (FC) package has been developed. A chip having an integrated circuit is directly embedded in a packaging substrate, to eliminate the use of wire bonding. As a result, such a package can have its overall size greatly reduced and electrical functionality increased.

As shown in FIG. 1, a conventional embedded semiconductor package 1 is shown, which comprises: a core layer 10 having opposing first and second surfaces 10a and 10b and an opening 100 penetrating the first and second surfaces 10a and 10b, a chip 11 accommodated in the opening 100, a circuit build-up structure 13 formed on the first and second surfaces 10a and 10b of the core layer 10 and on the chip 11, and a solder mask layer 16 formed on the circuit build-up structure 13.

The chip 11 has an active surface 11a and a non-active surface 11b. A plurality of electrode pads 110 are formed on the active surface 11a. The opening 100 is filled by an adhesive material 12, so as to position the chip 11 in the opening 100. The circuit build-up structure 13 has at least one dielectric layer 130, a circuit layer 131 formed on the dielectric layer 130, and a plurality of conductive vias 132 formed in the dielectric layer 130 and electrically connected with the electrode pads 100 and the circuit layer 131.

The solder mask layer 16 has a plurality of openings 160, allowing a portion of a surface of the circuit layer 131 to be exposed therefrom and function as conductive pads that can be electrically connected with electronic devices.

However, the conventional semiconductor package 1, since having the core layer 10, has its overall structure increased in thickness, thereby making it difficult to conform the low-profile requirement.

In addition, in the method of fabricating a conventional semiconductor package 1, the chip 11 must be embedded before making the circuit buildup structure 13, which is then followed by a test. Therefore, when the semiconductor package 1 is found to be defective, regardless which of the chip 11, the circuit build-up structure 13 or the core layer 10 is defective, the whole semiconductor package 1 is abandoned. This undesirably causes wastage of materials and also increases the production cost.

Moreover, the chip 11 is electrically connected to external electronic components through the circuit layer 131, leading to prolonged signal pathway and reduced electrical functionality of the semiconductor package 1.

Therefore, there is an urgent need to solve the foregoing problems.

### SUMMARY OF THE INVENTION

In order to achieve the foregoing objectives, the present invention provides a semiconductor package, comprising: an encapsulating layer, having a first surface, a second surface opposing the first surface, and at least one opening formed via the first surface of the encapsulating layer; a circuit layer formed and embedded in the encapsulating layer via the first surface of the encapsulating layer; and at least one electronic component disposed in the opening and being exposed from the first surface.

In an embodiment, the opening is not in communication with the second surface.

In an embodiment, the electronic component is not exposed from the second surface.

The present invention further provides a method of fabricating a semiconductor package, comprising: providing a carrier having a circuit layer; forming at least one blocking member on the carrier; forming on the carrier an encapsulating layer that has a first surface coupled to the carrier and a second surface opposing the first surface, and encapsulates the circuit layer and the blocking member; removing the carrier and the blocking member, allowing an opening to be formed in the encapsulating via the first surface thereof layer; and disposing at least one electronic component in the opening.

In an embodiment, the blocking member is formed by electro-plating or printing method.

In an embodiment, the encapsulating layer is formed by molding or lamination. The encapsulating layer is made of a molding compound, a dielectric layer or an optic insulative material.

In an embodiment, the method further comprises forming on the second surface of the encapsulating layer a circuit structure that is electrically connected with the circuit layer. In an embodiment, the method further comprises forming an insulative protecting layer on the second surface of the encapsulating layer such that a portion of the circuit structure is exposed from the insulative protecting layer. In an embodiment, the circuit structure has a plurality of conductive pillars formed in the encapsulating layer and electrically connecting the circuit structure to the circuit layer. The conductive pillars are formed by forming a plurality of through holes in the encapsulating layer via the second surface thereof by mechanical drilling or exposure and development methods, and filling the through holes with the conductive materials.

In an embodiment, the method further comprises forming an insulative protecting layer on the first surface of the encapsulating layer, allowing a portion of the circuit layer to be exposed from the insulative protecting layer.

In an embodiment, the method further comprises disposing on the first surface of the encapsulating layer a stacking member that is electrically connected with the circuit layer or electronic devices.

In an embodiment, the method further comprises disposing a stacking member on the second surface of the encapsulating layer.

In an embodiment, the method further comprises forming a redistribution structure on the first surface of the encapsulating layer and the circuit layer or on the second surface.

Accordingly, the semiconductor package and the method of fabricating the same according to present invention eliminate the use of a conventional core layer. Therefore, the semiconductor package has a reduced overall thickness and a reduced overall cost.

In addition, through forming a blocking member in the encapsulating layer, which is then removed to form an opening, the circuit layer and the electronic component can be individually tested to discard the defectives in advance of placing the electronic component, so as to prevent the material wastage problem that the entire semiconductor package is always abandoned if being defecture.

Moreover, the electronic component can be directly electrically connected with the stacking member without the need of a circuit layer, hence the signal pathway can be reduced and the electrical functionality can be enhanced.

### BRIEF DESCRIPTION OF THE DRAWINGS

FIG. 1 is a cross-sectional schematic view of a conventional semiconductor package;

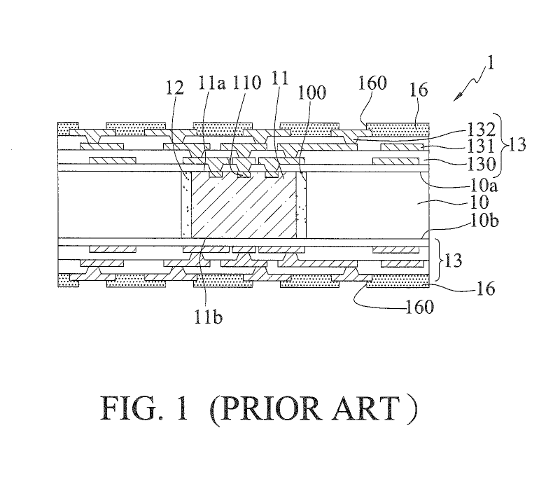

FIGS. 2A to 2G are cross-sectional views showing a method of fabricating a semiconductor package according to the present invention;

FIG. 3 is a latter procedures of FIG. 2G; and

FIGS. 4 and 5 are different embodiments from FIG. 2G.

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

It should be noted that all the drawings are not intended to limit the present invention. Various modification and variations can be made without departing from the spirit of the present invention. Further, terms, such as “upper”, “left”, “right”, “first”, “second” and “one” etc., are merely for illustrative purpose and should not be construed to limit the scope of the present invention.

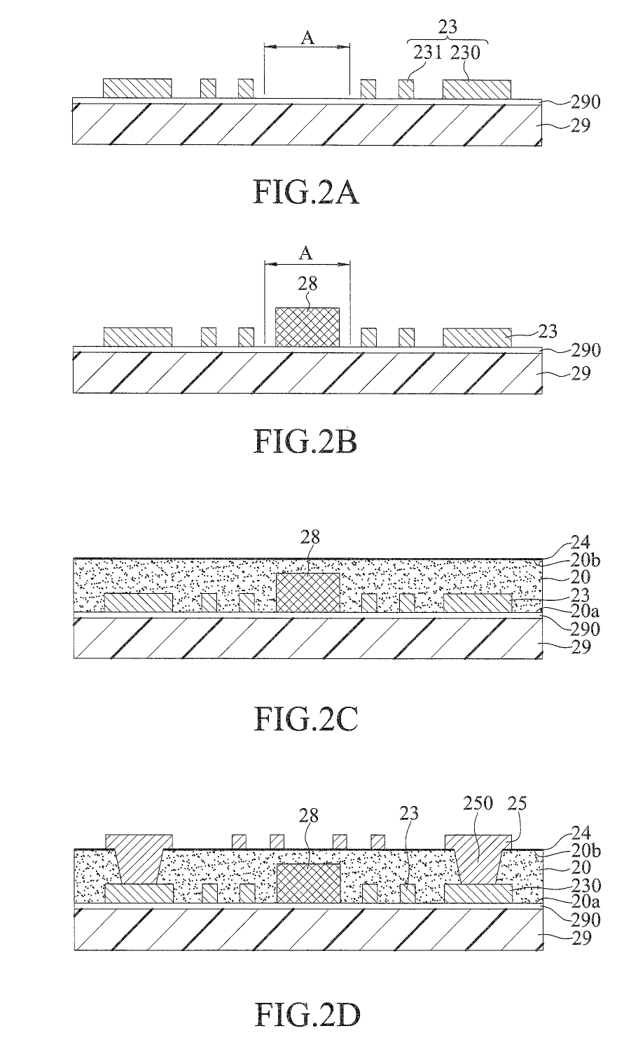

FIGS. 2A to 2G are cross-sectional views showing a method of fabricating a coreless semiconductor package 2 according to the present invention.

As shown in FIG. 2A, a carrier 29 having an attaching layer 290 is provided, and a circuit layer 23 is formed on the attaching layer 290 of the carrier 29.

In an embodiment, the carrier 29 is a metal board, a semiconductor wafer, or a glass board, and the attaching layer 290 is a release film, an adhesive material, an insulating material, or a composite material such as a foil having a seed layer.

In an embodiment, the carrier 29 is defined with a placement area A, and the circuit layer 23 is formed outside the placement area A.

In an embodiment, the circuit layer 23 comprises a plurality of conductive traces 231 and a plurality of conductive pads 230, and the circuit layer 23 can be formed by, but not limited to, an electro-plating method or other methods.

As shown in FIG. 2B, a blocking member 28 is formed on the attaching layer 290 within the placement area A of the carrier 29.

In an embodiment, the blocking member 28 is formed by an electro-plating method, or by a screen printing method and made of polymers.

As shown in FIG. 2C, an encapsulating layer 20 is formed on the attaching layer 290 to encapsulate the circuit layer 23 and the blocking member 28, and the circuit layer 23 is embedded in the encapsulating layer 20. In an embodiment, the encapsulating layer 20 has a first surface 20a and a second surface 20b opposing the first surface 20a, and the first surface 20a is attached to the attaching layer 290.

In an embodiment, the encapsulating layer 20 is formed by a molding or lamination process, and the encapsulating layer 20 is made of, but not limited to, a molding compound, a dielectric material or a photo-imageable dielectric material.

A conductive layer 24 is formed on the second surface 20b of the encapsulating layer 20 for a subsequent process of forming the circuit to be performed. In an embodiment, the conductive layer 24 such as a copper coil is pressed on the second surface 20b of the encapsulating layer 20, and then the conductive layer 24 and the encapsulating layer 20 are combined to be coupled onto the attaching layer 290. Alternatively, after the encapsulating layer 20 is pressed onto the attaching layer 290, the conductive layer 24 is formed on the encapsulating layer 20.

In another embodiment, the conductive layer 24 is formed on the second surface 20b of the encapsulating layer 20 by a sputtering process.

As shown in FIG. 2D, through the conductive layer 24, a circuit structure 25 is formed on the second surface 20b of the encapsulating layer 20 by an electro-plating process, and the circuit structure 25 has conductive pillars 250 formed in the encapsulating layer 20 and electrically connected with the conductive pads 230 of the circuit layer 23. In an embodiment, the conductive pillars 250 are formed by forming through holes in the encapsulating layer 20 via the second surface 20b thereof by a laser process, and filling the through holes with a conductive material, or using a photo-imageable dielectric material to make the encapsulating layer 20 and through exposure and development processes to form the conductive material in the through holes.

As shown in FIG. 2E, the excessive portion of the conductive layer 24, along with the carrier 29, the attaching layer 290 and the blocking member 28 are removed, allowing an opening 200 to be formed in the encapsulating layer 20 via the first surface 20a corresponding in position to the placement area A.

In an embodiment, a portion of the circuit structure 25 outside of the conductive traces layer 24 is removed, i.e., the remaining portion of the circuit structure 25 under the conductive traces layer 24 is retained.

As shown in FIG. 2F, an insulative protecting layer 26 such as a solder mask layer is formed on first and second surfaces 20a and 20b of the encapsulating layer 20. The insulative protecting layer 26 has a plurality of openings 260, allowing a portion of a surface of the conductive pads 230 and the circuit structure 25 (acting as conductive pads 251) to be exposed therefrom, for connecting with external electronic devices. As shown in FIG. 2G, at least one electronic component 21 is disposed in the opening 200, and the opening 200 is filled with an adhesive material 22, such that the electronic component 21 is held in position in the opening 200.

In an embodiment, the electronic component 21 can be an active component, a passive component, or a combination thereof. The active component can be a semiconductor chip, and the passive component can be a resistor, a capacitor and an inductor. In an embodiment, the electronic component 21 is a passive component, and has electrodes 210 formed on the left and right sides thereof.

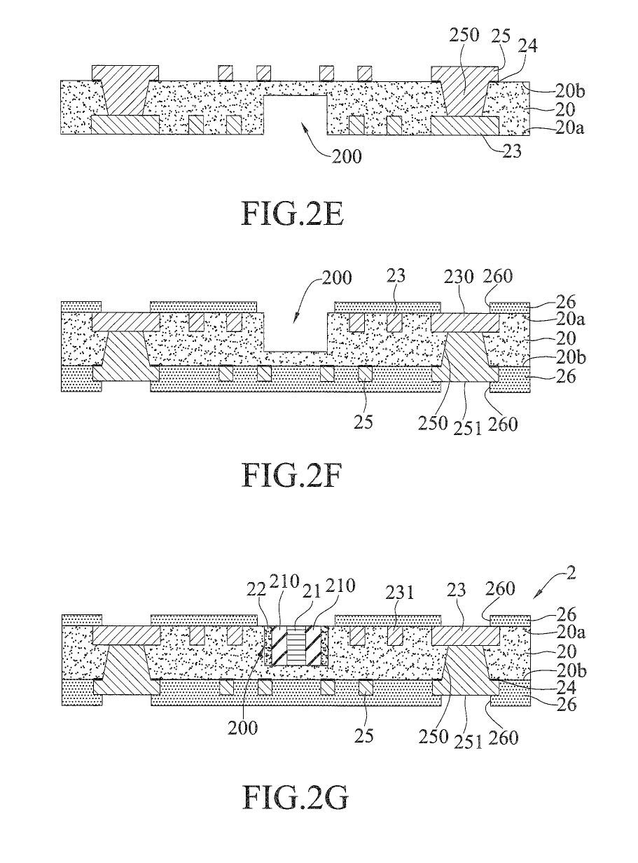

In an embodiment, the electronic component 21 is electrically connected to the circuit layer 23 via a wire bonding method. In the latter processes, as shown in FIG. 3, the circuit layer 23 (i.e., the conductive pads 230) and the electrodes 210 of the electronic component 21 can be coupled to a stacking member 30 via a plurality of conductive elements 27, such as a solder material or a copper pillar, to form a stacked packaging unit 3.

In an embodiment, the stacking member 30 is a semiconductor chip, a chip wafer, an interposer or a package.

In other embodiments, other electronic devices can be coupled to the second surface 20b of the encapsulating layer 20 and the circuit structure 25.

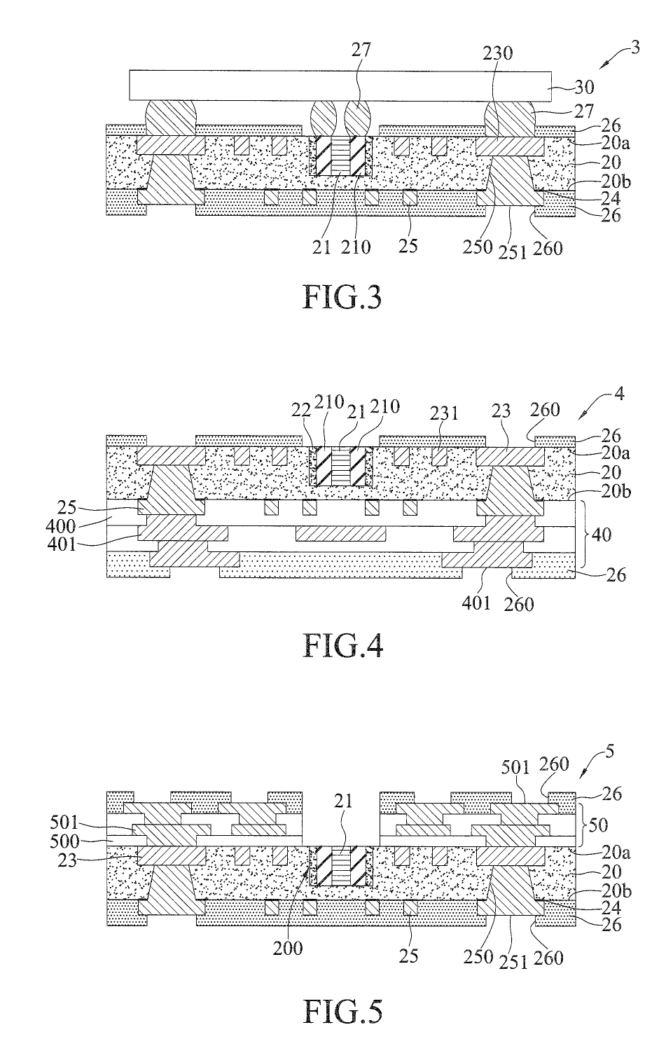

As shown in FIG. 4, after the excessive portion of conductive layer 24 is removed, a redistribution structure 40 is formed on the second surface 20b of the encapsulating layer 20 by a redistribution layer (RDL) process. The redistribution structure 40 is electrically connected with the circuit structure 25. Subsequently, an insulative protecting layer 26 is formed on the redistribution structure 40, with a portion of a surface of the redistribution structure 40 being exposed, for other external components to be coupled thereto in subsequent processes.

Alternatively, as shown in FIG. 5, after the carrier 29, the attaching layer 290 and the blocking member 28 are removed, a redistribution layer (RDL) process is performed to form a redistribution structure 50 on the first surface 20a of the encapsulating layer 20, and after the redistribution structure 50 is electrically connected with the circuit layer 23, the insulative protecting layer 26 is formed on the redistribution structure 50, with a portion of a surface of the redistribution structure 50 being exposed, for other external components to be coupled thereto in subsequent processes. In an embodiment, the redistribution structure 50 does not cover the opening 200, allowing the electronic component 21 to be placed in subsequent processes.

In an embodiment, the redistribution structures 40 and 50 have, respectively, at least one circuit part 401, 405 and at least one dielectric layer 400, 500, which are interstacked with the circuit part 401, 405. The dielectric layer 400, 500 is formed on the encapsulating layer 20, and the circuit par 401, 501 is used for electrical connection.

The semiconductor package 2 according the present invention does not have a core layer, such that the thickness of the overall structure, as well as the cost can be reduced.

Moreover, in the method of fabricating the semiconductor package according to present invention, a space is reserved for the electronic component 21 to be accommodated therein. That is, an opening 200 for accommodating the electronic component 21 is formed after a blocking member 28 formed in the encapsulating layer 20 is removed. Before the electronic component 21 is accommodated in the opening 200, the circuit layer 23 (or the circuit structure 25) and the electronic component 21 can be individually tested in advance to discard the defectives, such that the material wastage problem due to that the entire semiconductor package 2 needs to be discarded whenever a defective semiconductor package 2 is found can be prevented, thereby saving the overall cost.

Further, the electronic component 21 and the stacking member 30 can be directly electrically connected, without the need of a circuit layer 23, such that the signal pathway of the stacked package unit 3 is reduced, and the electrical functionality of the stacked package unit 3 is increased.

The present invention further provides a semiconductor package 2, comprising: an encapsulating layer 20, a circuit layer 23, and at least one electronic component 21.

The encapsulating layer 20 has a first surface 20a, a second surface 20b opposing the first surface 20a, and at least one opening 200 formed in the encapsulating layer 20 via the first surface 20a thereof. In an embodiment, the opening 200 is free from being connected to the second surface 20b. In an embodiment, the encapsulating layer 20 is made of a molding compound, a dielectric material or a photo-imageable dielectric material.

The circuit layer 23 is formed and embedded in the encapsulating layer 20 via the first surface 20a of the encapsulating layer 20.

The electronic component 21 is disposed in the opening 200, and exposed from the first surface 20a, but not the second surface 20b. The electronic component 21 is an active component, a passive component, or a combination thereof.

In an embodiment, the semiconductor package 2 further comprises a circuit structure 25 formed in the second surface 20b of the encapsulating layer 20 and electrically connected with the circuit layer 23. In another embodiment, the semiconductor package 2 further comprises an insulative protecting layer 26 formed on the second surface 20b of the encapsulating layer 20, with a portion of a surface of the circuit structure 25 being exposed.

In an embodiment, the semiconductor package 2 further comprises an insulative protecting layer 26, formed in the first surface 20a of the encapsulating layer 20, with a portion of a surface of the circuit layer 23 being exposed.

In an embodiment, the semiconductor package 2 further comprises a plurality of conductive elements 27 disposed on a portion of a surface of the circuit layer 23.

In an embodiment, the semiconductor package 2 further comprises a plurality of conductive elements 27 disposed on the electronic component 21.

In an embodiment, a stacking member 30 is disposed on the first surface 20a of the encapsulating layer 20, and electrically connected to the circuit layer 23 or the electronic component 21.

In an embodiment, a stacking member 30 is disposed on the second surface 20b of the encapsulating layer 20, and electrically connected to the circuit structure 25.

In an embodiment, the semiconductor package 4 further comprises a redistribution structure 40 formed on the second surface 20b of the encapsulating layer 20.

In an embodiment, the semiconductor package 5 further comprises a redistribution structure 50 formed on the first surface 20a of the encapsulating layer 20.

In summary, the semiconductor package and the method of fabricating the same according to the present invention involve using a coreless design to reduce the thickness of the overall structure of the package, so as to reach the objective of low-profile and reduced cost.

Before the electronic components is placed in the predetermined space, the circuit layer and the electronic component can be individually tested, to discard the defectives, so as to prevent the entire semiconductor package being abandoned, causing wastage of materials.

Moreover, disposing the electronic component after disposing wires allows the electronic component to be directly electrically connected to the stacking member, without a need of a circuit layer. Hence, the signal pathway can be reduced so as to increase the electrical functionality.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor package, comprising:
an encapsulating layer having a first surface, a second surface opposing the first surface, and at least one opening formed via the first surface;
a circuit layer formed and embedded in the encapsulating layer via the first surface of the encapsulating layer; and
at least one electronic component disposed in the opening and exposed from the first surface.

2. The semiconductor package of claim 1, wherein the opening is free from being in communication with the second surface.

3. The semiconductor package of claim 1, wherein the encapsulating layer is made of molding compounds, dielectric materials or photo-imageable dielectric materials.

4. The semiconductor package of claim 1, wherein the electronic component is free from being exposed from the second surface.

5. The semiconductor package of claim 1, further comprising a circuit structure formed on the second surface of the encapsulating layer and electrically connected to the circuit layer.

6. The semiconductor package of claim 5, further comprising an insulative protecting layer formed on the second surface of the encapsulating layer and exposing a portion of a surface of the circuit structure.

7. The semiconductor package of claim 1, further comprising an insulative protecting layer formed on the first surface of the encapsulating layer and exposing a portion of a surface of the circuit layer.

8. The semiconductor package of claim 1, further comprising a plurality of conductive elements disposed on a portion of a surface of the circuit layer.

9. The semiconductor package of claim 1, further comprising a plurality of conductive elements disposed on the electronic component.

10. The semiconductor package of claim 1, further comprising a stacking member disposed on the first surface of the encapsulating layer and electrically connected with the circuit layer or the electronic component.

11. The semiconductor package of claim 1, further comprising a stacking member disposed on the second surface of the encapsulating layer.

12. The semiconductor package of claim 1, further comprising a redistribution structure formed on the first surface of the encapsulating layer and the circuit layer.

13. The semiconductor package of claim 1, further comprising a redistribution structure formed on the second surface of the encapsulating layer.

14. A method of fabricating a semiconductor package, comprising:
providing a carrier having a circuit layer;
forming at least one blocking member on the carrier;
forming on the carrier an encapsulating layer that has a first surface coupled to the carrier and a second surface opposing the first surface, and encapsulates the circuit layer and the blocking member;
removing the carrier and the blocking member, allowing an opening to be formed in the encapsulating layer via the first surface thereof; and
disposing at least one electronic component in the opening.

15. The method of claim 14, wherein the encapsulating layer is formed by molding or lamination.

16. The method of claim 14, wherein the blocking member is formed by electro-plating or printing.

17. The method of claim 14, further comprising forming on the second surface of the encapsulating layer a circuit structure that is electrically connected to the circuit layer.

18. The method of claim 17, wherein the circuit structure has a plurality of conductive pillars formed in the encapsulating layer and electrically connecting the circuit structure to the circuit layer.

19. The method of claim 18, wherein the conductive pillars are formed by forming a plurality of through holes in the second surface of the encapsulating layer via the second surface thereof by laser, mechanical drilling, or exposure and development, and filling the through holes with a conductive material.

20. The method of claim 17, further comprising forming an insulative protecting layer on the second surface of the encapsulating layer, allowing a portion of a surface of the circuit structure to be exposed from the insulative protecting layer.

21. The method of claim 14, further comprising forming an insulative protecting layer on the first surface of the encapsulating layer, allowing a portion of a surface of the circuit structure to be exposed from the insulative protecting layer.

22. The method of claim 14, further comprising disposing on the first surface of the encapsulating layer a stacking member that is electrically connected to the circuit layer or the electronic component.

23. The method of claim 14, further comprising disposing a stacking member on the second surface of the encapsulating layer.

24. The method of claim 14, further comprising forming a redistribution structure on the first surface of the encapsulating layer.

25. The method of claim 14, further comprising forming a redistribution structure on the second surface of the encapsulating layer.
